(19) United States
(12) Patent Application Publication
(10) Pub. No.: US 2004/0065964 A1
(43) Pub. Date: Apr. 8, 2004

(54) Semiconductor package with thermal enhance film and manufacturing method thereof

(75) Inventors: Chun-Chi Lee, Kaohsiung (TW); Chih-Huang Chang, Yungkang City (TW); Chian-Chi Lin, Tainan (TW); Cheng-Yin Lee, Tainan (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/664,981

(22) Filed: Sep. 22, 2003

(30) Foreign Application Priority Data
Oct. 2, 2002 (TW) 091122679

(51) Int. Cl. H01L 23/48

(52) U.S. Cl. 257/783

(57) ABSTRACT

A semiconductor package with a thermal enhance film mainly comprises a substrate, a semiconductor chip and a thermal enhance film. The semiconductor chip is electrically connected to the substrate and the thermal enhance film is formed on the back surface of the semiconductor chip. Therein, the thermal enhance film can be regarded as a heat transmission layer to transmit the heat to the outside and upgrade the thermal efficiency of the semiconductor package. In addition, the thermal enhance film can be made of a material comprising polymer. For example, the thermal enhance film is a thermally conductive polymer layer and can be regarded as a buffer layer to prevent the active surface of the semiconductor chip from being chipped. Furthermore, a manufacturing method to manufacture the semiconductor package is provided.

### BACKGROUND OF THE INVENTION

1. Field of Invention

This invention relates to a semiconductor package. More particularly, the present invention is related to a semiconductor package with a thermal enhance film and manufacturing method thereof.

2. Related Art

Originally, a semiconductor package is formed by the processes of singulating a wafer into a plurality of semiconductor chips, attaching one of the semiconductor chips onto a substrate and electrically connecting the semiconductor chip to the substrate via a plurality of conductive wires, encapsulating the semiconductor chip, the substrate and the conductive wires by an encapsulation. Similarly, the semiconductor package also can be formed by the method of flip chip bonding. However, the wafer is made of a material selected from silicon, which is crumbly. Accordingly, the active surface of the wafer is easily to be broken and chipping so as to cause the electrical circuits to be shortened and damaged.

Therefore, providing another semiconductor package and a manufacturing method thereof to solve the mentioned-above disadvantages is the most important task in this invention.

### SUMMARY OF THE INVENTION

In view of the above-mentioned problems, an objective of this invention is to provide a thermal enhance film formed on the back surface of the semiconductor chip and a manufacturing method thereof to upgrade the efficiency of the heat transmission of the semiconductor package.

Moreover, another object of this invention is to provide a polymer film, formed on a back surface of a wafer prior to the process of singulating the wafer into a plurality of semiconductor chips so as to prevent the active surface of the wafer from being chipping.

To achieve the above-mentioned objective, a semiconductor package is provided, wherein the semiconductor package mainly comprises a substrate, a semiconductor chip and a thermal enhance film. Therein the semiconductor chip is electrically connected to the substrate via a plurality of bumps and the thermal enhance film is formed on the back surface of the semiconductor chip. The thermal enhance film has metal powder, thermally conductive powder therein or is made of thermally conductive material, for example a thermally conductive tape, a thermally conductive epoxy and a thermally conductive polymer film, so the efficiency of the heat transmission of the semiconductor package can be upgraded.

As mentioned above and to achieve another above-mentioned objective, the thermal enhance film can be made of polymer. Namely, a thermally conductive polymer film can be formed on the back surface of the wafer prior to the process of singulating the wafer into a plurality of semiconductor chips, so the active surface of the wafer will be prevented from being chipping when the singulation process is performed. Thereby the active surface of the wafer can be prevented from being chipping by the thermally conductive polymer film in that the polymer film is provided as a buffer layer on the back surface of the wafer when the wafer is singulated or cut.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of a semiconductor package with a thermal enhance film according to the first embodiment of the present package;

FIG. 2 is a cross-sectional view of a semiconductor package with a thermal enhance film according to the second embodiment of the present package;

FIG. 3 is a cross-sectional view of a semiconductor package with a thermal enhance film according to the third embodiment of the present package;

FIG. 4 is a cross-sectional view of a semiconductor package with a thermal enhance film according to the fourth embodiment of the present package;

FIG. 5 is a cross-sectional view of a semiconductor package with a thermal enhance film according to the fifth embodiment of the present package;

FIG. 6 is a cross-sectional view of a semiconductor package with a thermal enhance film according to the sixth embodiment of the present package; and

FIG. 7 is a flow chart illustrating the process flow of a manufacturing method of the semiconductor package of FIG. 1.

### DETAILED DESCRIPTION OF THE INVENTION

The semiconductor package with a thermal enhance film and a manufacturing method thereof according to the preferred embodiment of this invention will be described herein below with reference to the accompanying drawings, wherein the same reference numbers refer to the same elements.

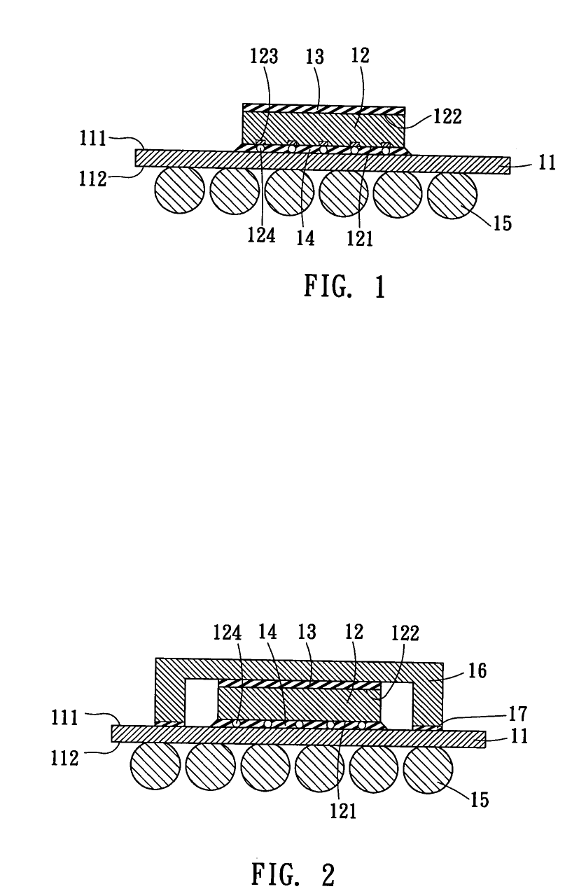

In accordance with a first preferred embodiment as shown in FIG. 1, there is provided a semiconductor package with a thermal enhance layer. The semiconductor package mainly comprises a substrate 11, a semiconductor chip 12 and a thermal enhance layer 13. The substrate 11 has an upper surface 111 and an opposite lower surface 112. The semiconductor chip 12 has an active surface 121, a back surface 122, a plurality of bonding pads 123 formed thereon, and a plurality of bumps 124, for example solder bumps and gold bumps, formed on the bonding pads 123. Besides, the thermal enhance layer 13, for example a thermal enhance film, a thermal enhance tape, a thermally conductive epoxy, and a thermally conductive polymer layer, is formed on the back surface 122 of the semiconductor chip 12. The coefficient of thermal expansion of the substrate 11 is different from that of the semiconductor chip 12, so an underfill 14 or similar fillers are disposed at a gap between the substrate 11 and the semiconductor chip 12 to prevent the substrate 11 and the semiconductor chip 12 from being damaged by the thermal stress caused by the change of the temperature. In addition, a plurality of solder balls 15 are mounted on the lower surface 112 of the substrate 11 so as to be an electrical connection path to electrical connect to external devices.

As mentioned above, when the thermal enhance layer 13 is a thermally conductive epoxy, it can be formed on the back surface 122 of the semiconductor chip 12 by the method of screen-printing. Moreover, when the thermal enhance layer 13 is a thermally conductive tape or thermally conductive film, it can be directly attached on the back surface 122 of the semiconductor chip 12.

Next, referring to FIG. 2., a second preferred embodiment is shown. When the thermal enhance layer 13 is made of thermally conductive epoxy and before the thermally conductive epoxy is fully cured, the thermally conductive epoxy is also regarded as an adhesive. Thus a heat spreader 16 with a cap-like shape can be connected to the back surface 122 of the semiconductor chip 12 via the thermally conductive epoxy and attached to the upper surface 111 of the substrate 11 via another adhesive 17. Therefore, the heat arisen out of the semiconductor chip 12 can be transmitted to the outside via the heat spreader 16 and the thermal enhance layer 13 (thermally conductive epoxy), and the efficiency of the heat transmission of the semiconductor package will be upgraded.

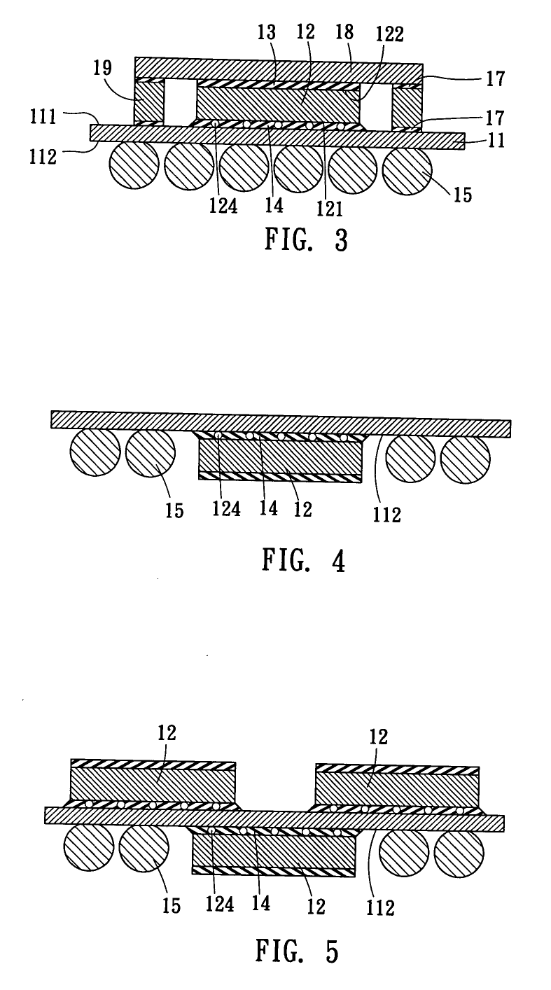

Similar to the above mentioned, a third embodiment is shown in FIG. 3. In FIG. 3, a heat spreader 18 with a flat shape is attached to the back surface 122 of the semiconductor chip 12 via the thermal enhance layer 13 in order to upgrade the efficiency of the heat transmission of the semiconductor package. Besides, a stiffener ring 19 is disposed on the substrate 11 and surrounds the semiconductor chip 12 so as to be a supporter to support the heat spreader 18 and to prevent the heat spreader 18 from being tilted and deformed.

Furthermore, a fourth embodiment is shown in FIG. 4, a semiconductor chip 12 with a thermal enhance layer 13 formed on the back surface 122 thereof is disposed on the lower surface 112 of the substrate 11.

Next, a fifth embodiment is provided in FIG. 5. Two semiconductor chips 12 are disposed on the upper surface 111 of the substrate 11 and another semiconductor chip 12 is disposed on the lower surface 112 of the substrate 11. Therein the semiconductor chips all has a thermal enhance layer 13 formed on the back surface 122 of each semiconductor chip 12. Besides, the semiconductor chip 12 can be electrically connected to the substrate via conductive wires (not shown).

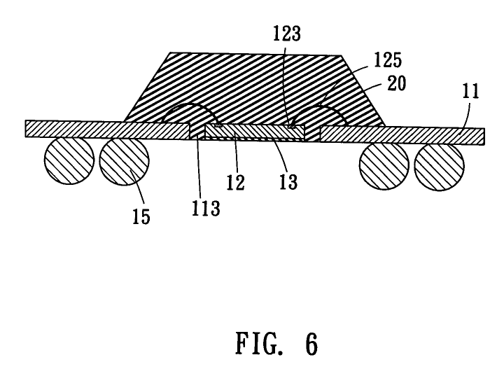

Moreover, as shown in FIG. 6, a sixth embodiment of this invention is provided. The substrate 11 has an opening 113 and the semiconductor chip 12 with a thermal enhance layer 13 is disposed in the opening 113 and electrically connected to the substrate 11 via conductive wires 125, for example gold wires. Finally, an encapsulation 20 encapsulates the semiconductor chip 12 and the conductive wires 125, and exposes the thermal enhance layer 13. Thus the heat arisen out of the semiconductor chip 12 can be transmitted to the outside through the thermal enhance layer 13. It is should be noted that the reference numeral of each element in FIGS. 2, 3, 4, 5 and 6 corresponds to the same reference numeral of each element in FIG. 1.

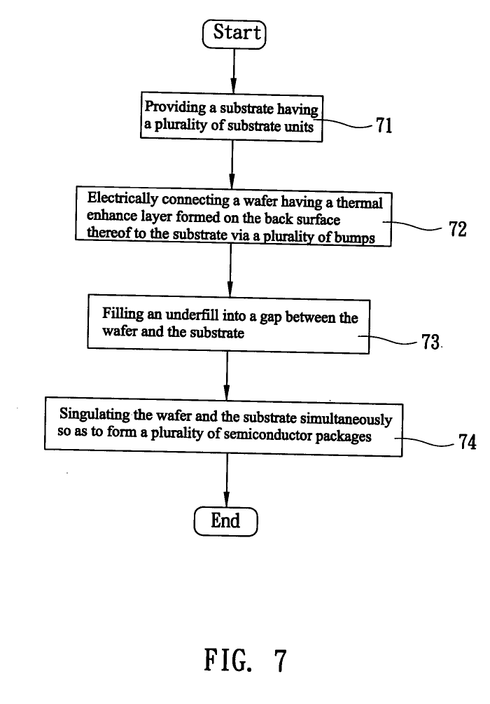

Next, referring to FIG. 7, a flow chart of the manufacturing method of the semiconductor package is disclosed. First, in step 71, a substrate having a plurality of substrate units, for example an organic substrate and a ceramic substrate, is provided. Then, in step 72, a wafer, having a plurality of semiconductor chips, with an active surface and a back surface is provided. Therein a thermal enhance layer is formed on the back surface of the wafer and a plurality of bonding pads formed on the active surface of the wafer. Furthermore, the active surface of the wafer faces the upper surface of the substrate and electrically connects to the substrate via a plurality of bumps. Afterwards, in step 73, an underfill is filled into a gap between the wafer and the substrate so as to prevent the semiconductor package from being damaged by CTE mismatch. Finally, in step 74, the wafer and the substrate are singulated by cutting simultaneously so as to form a plurality of semiconductor packages at least having one of the substrate units and one of the semiconductor chips.

As mentioned above, the thermal enhance layer is a thermally conductive polymer layer and formed on the back surface of the wafer. Accordingly, in step 73, when the wafer is singulated by cutting, the thermal enhance layer can be regarded as a buffer layer to prevent the active surface of the wafer from being chipping and damaged.

Besides, after step 74 is performed, a step of attaching a heat spreader on the back surface of the semiconductor chip can be performed to increase the efficiency of the heat transmission of the semiconductor package.

Although the invention has been described in considerable detail with reference to certain preferred embodiments, it will be appreciated and understood that various changes and modifications may be made without departing from the spirit and scope of the invention as defined in the appended claims.

What is claimed is:

1. A semiconductor package, comprising:
a substrate having an upper surface and a lower surface opposed to the upper surface;
a semiconductor chip having an active surface, a back surface opposed to the active surface and a plurality of bonding pads formed on the active surface;
a plurality of conductive devices, the conductive devices formed on the bonding pads and electrically connecting the active surface of the semiconductor chip and the upper surface of the substrate; and
a thermal enhance layer formed on the back surface of the semiconductor chip.

2. The semiconductor package of claim 1, further comprising an underfill disposed between the active surface of the semiconductor chip and the upper surface of the substrate.

3. The semiconductor package of claim 1, wherein a material of the thermal enhance layer comprises thermally conductive polymer layer.

4. The semiconductor package of claim 3, wherein a material of the thermally conductive polymer layer comprises thermally conductive film.

5. The semiconductor package of claim 3, wherein a material of the thermally conductive polymer layer comprises thermally conductive epoxy.

6. The semiconductor package of claim 1, further comprising a heat spreader attached on the thermal enhance layer.

7. The semiconductor package of claim 6, wherein the heat spreader is a flat heat spreader.

8. The semiconductor package of claim 6, wherein the spreader is a cap-like heat spreader.

9. The semiconductor package of claim 8, further comprising an adhesive connecting the substrate and the heat spreader.

10. The semiconductor package of claim 6, wherein a material of the heat spreader comprises copper.

11. The semiconductor package of claim 6, further comprising a stiffener ring connecting the substrate and the heat spreader.

12. The semiconductor package of claim 6, wherein the coefficient of the thermal expansion of the heat spreader is substantially the same as that of the semiconductor chip.

13. The semiconductor package of claim 6, wherein a material of the heat spreader comprises silicon.

14. The semiconductor package of claim 1, wherein the conductive devices are conductive bumps, and the active surface of the semiconductor chip faces and connects to the upper surface of the substrate via the conductive bumps.

15. The semiconductor package of claim 1, wherein the conductive devices are conductive wires, and the back surface of the semiconductor chip faces and connects to the upper surface of the substrate via the thermal enhance layer.

16. The semiconductor package of claim 1, wherein the substrate has an opening and the semiconductor chip is disposed in the opening.

17. The semiconductor package of claim 1, further comprising a plurality of solder balls formed on the lower surface of the substrate.

18. The semiconductor package of claim 1, further comprising an additional semiconductor chip attached on the lower surface of the substrate.

19. A semiconductor package manufacturing method, comprising:
providing a wafer having an active surface and a back surface, wherein the active surface has a plurality of bonding pads and a plurality of bumps formed on the bonding pads, and the back surface has a thermally conductive polymer layer formed thereon;
providing a substrate having an upper surface and a lower surface;
attaching the active surface of the wafer onto the upper surface of the substrate via the bumps;
singulating the wafer, the thermally conductive polymer layer and the substrate simultaneously to form a plurality of semiconductor packages, each semiconductor package having an substrate unit and a semiconductor chip; and
forming a plurality of balls on each of the substrate units.

20. The semiconductor package manufacturing method of claim 19, further comprising disposing an underfill between one of the semiconductor chips and one of the substrate units.

21. The semiconductor package manufacturing method of claim 19, wherein the thermally conductive polymer layer is a thermally conductive film.

22. A semiconductor wafer structure, comprising:
a semiconductor wafer having an active surface, a back surface opposed to the active surface and a plurality of bonding pads formed on the active surface;
a plurality of conductive devices formed on the bonding pads; and
a polymer layer formed on the back surface of the semiconductor wafer.

23. The semiconductor wafer structure of claim 22, wherein a material of the polymer layer comprises thermally conductive polymer.

24. The semiconductor wafer structure of claim 23 wherein a material of the thermally conductive polymer layer comprises thermally conductive film.

25. The semiconductor wafer structure of claim 23, wherein a material of the thermally conductive polymer layer comprises thermally conductive epoxy.

26. The semiconductor wafer structure of claim 23, wherein the thermally conductive polymer layer has metal powder formed therein.

27. The semiconductor wafer structure of claim 23, wherein the thermally conductive polymer layer has thermally conductive powder formed therein.
